(19) United States
(12) Patent Application Publication
(10) Pub. No.: US 2015/0076559 A1
(43) Pub. Date: Mar. 19, 2015

(54) INTEGRATED CIRCUITS WITH STRAINED SILICON AND METHODS FOR FABRICATING SUCH CIRCUITS

(71) Applicant: GLOBALFOUNDRIES, Inc., Grand Cayman (KY)

(72) Inventors: Kai Frohberg, Dresden (DE); Torsten Huisinga, Dresden (DE); Egon Ronny Pfuetzner, Dresden (DE)

(73) Assignee: GLOBALFOUNDRIES, Inc., Grand Cayman (KY)

(21) Appl. No.: 14/028,876

(22) Filed: Sep. 17, 2013

(51) Int. Cl. H01L 29/165; H01L 29/06; H01L 21/762

(52) U.S. Cl. CPC H01L 29/165; H01L 21/76283; H01L 29/0649; H01L 21/76272
USPC 257/190; 438/413

(57) ABSTRACT

Integrated circuits with strained silicon and methods for fabricating such integrated circuits are provided. An integrated circuit includes a stack with a surface layer, an intermediate layer, and a base layer, where the surface layer overlies the intermediate layer, and the intermediate layer overlies the base layer. The surface layer and the base layer include strained silicon, where the silicon atoms are stretched beyond a normal crystalline silicon interatomic distance. The intermediate layer includes crystalline silicon germanium.

### TECHNICAL FIELD

The technical field generally relates to integrated circuits and methods for fabricating integrated circuits, and more particularly relates to integrated circuits with a strained crystalline silicon substrate overlying a crystalline silicon germanium layer and methods for fabrication such integrated circuits.

### BACKGROUND

The semiconductor industry is continuously moving toward the fabrication of smaller and more complex microelectronic components with higher performance The majority of present day integrated circuits (ICs) are implemented by using a plurality of interconnected field effect transistors (FETs), also called metal oxide semiconductor field effect transistors (MOSFETs or MOS transistors). MOSFETs are typically manufactured on crystalline silicon wafers, and electrons move through the crystalline silicon between a source and a drain in a channel under a gate electrode.

Electrons move more easily through strained crystalline silicon, so MOSFETs on strained silicon tend to have higher performance than MOSFETs on relaxed silicon. This higher performance is evident in faster switching times with lower energy consumption, especially for N channel MOSFETs.

However, silicon crystals naturally form in a relaxed state, and strained silicon will revert to relaxed silicon unless some force or structure maintains the strain on the silicon crystalline lattice. It is more costly to produce a wafer with strained silicon, so many integrated circuits do not utilize strained silicon.

Accordingly, it is desirable to provide integrated circuits with a strained crystalline silicon material that can be used for MOSFETs and other electronic components. In addition, it is desirable to provide methods for fabricating such integrated circuits. Furthermore, other desirable features and characteristics of the present embodiment will become apparent from the subsequent detailed description and the appended claims, taken in conjunction with the accompanying drawings and this background of the invention.

### BRIEF SUMMARY

An apparatus is provided for an integrated circuit. The integrated circuit includes a stack with a surface layer, an intermediate layer, and a base layer, where the surface layer overlies the intermediate layer, and the intermediate layer overlies the base layer. The surface layer and the base layer include strained silicon, where the silicon atoms are stretched beyond a normal crystalline silicon interatomic distance. The intermediate layer includes crystalline silicon germanium.

An apparatus is provided for an integrated circuit in a different embodiment. The integrated circuit includes a crystalline silicon handle layer and a support dielectric overlying the handle layer. The integrated circuit also includes a stack overlying the support dielectric, where the stack includes a surface layer, an intermediate layer, and a base layer. The surface layer and the base layer include crystalline silicon, and the intermediate layer includes silicon germanium. The surface layer overlies the intermediate layer, the intermediate layer overlies the base layer, and the base layer overlies the support dielectric.

A method is provided for producing an integrated circuit. The method includes etching a trench in a silicon on insulator substrate, and forming a shallow trench isolation dielectric in the trench. A stack is created with stack sides adjacent the shallow trench isolation dielectric and a stack bottom overlying a buried dielectric. The stack includes a surface layer overlying an intermediate layer, where the intermediate layer overlies a base layer. The surface layer and base layer include crystalline silicon, and the intermediate layer includes silicon germanium. A bridge is formed overlying the stack and a portion of the shallow trench isolation dielectric, and the stack is suspended from the bridge by removing the shallow trench isolation dielectric from adjacent the stack sides and the buried dielectric from underneath the stack bottom. The stack is then supported by depositing a support dielectric underneath the stack bottom and adjacent to the stack sides.

### BRIEF DESCRIPTION OF THE DRAWINGS

The present embodiments will hereinafter be described in conjunction with the following drawing figures, wherein like numerals denote like elements, and wherein:

FIGS. 1-5 illustrate, in cross sectional views, a portion of an integrated circuit and methods for its fabrication in accordance with exemplary embodiments.

FIG. 6 illustrates, in a cut away perspective view, a portion of an exemplary embodiment of the integrated circuit at an intermediate manufacturing point;

FIGS. 7-9 illustrate, in cross sectional views, a portion of the integrated circuit and a continuation of methods for its fabrication in accordance with exemplary embodiments;

FIG. 10 illustrates, in a perspective view, a portion of an exemplary embodiment of the integrated circuit at another intermediate manufacturing point;

FIGS. 11-12 illustrate, in cross sectional views, a portion of the integrated circuit and a further continuation of methods for its fabrication in accordance with exemplary embodiments;

FIG. 13 illustrates, in a perspective view, a portion of an exemplary embodiment of the integrated circuit at yet another intermediate manufacturing point;

FIGS. 14-16 illustrate, in cross sectional views, a portion of the integrated circuit and a further continuation of methods for its fabrication in accordance with exemplary embodiments.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description.

In accordance with various embodiments contemplated herein, a silicon on insulator (SOI) substrate is used to produce a strained silicon surface for metal oxide semiconductor field effect transistors (MOSFETs) and other electronic components. The SOI substrate includes a device layer of monocrystalline silicon overlying a buried dielectric that in turn overlies a handle layer. A quadrilateral pattern of shallow trench isolation (STI) dielectrics are formed through the device layer so that silicon “islands” are formed within a quadrilateral STI dielectric. The STI dielectric extends through the buried dielectric to the handle layer. Most of the silicon island is etched away to leave a thin base layer of silicon overlying the buried oxide. A thicker intermediate layer of crystalline silicon germanium is then epitaxially grown overlying the base layer. The intermediate layer is strained because the germanium atoms are larger than the silicon atoms, so the natural silicon germanium crystal structure is compacted to match the natural silicon crystal structure from the base layer. A relatively thin surface layer of relaxed crystalline silicon is then epitaxially grown overlying the intermediate layer. This produces a monocrystalline stack with a relaxed base layer of silicon, a strained intermediate layer of silicon germanium, and a relaxed surface layer of silicon. A bridge is formed overlying a portion of the stack, and the bridge extends over the STI dielectric on opposite sides of the stack. The STI dielectric and the buried dielectric are then removed from around the sides and bottom of the stack, so the stack is suspended and freely hanging from the bridge. When the stack is suspended and released from the confines of the adjacent STI dielectric and buried dielectric, the relatively thick intermediate layer of silicon germanium relaxes, which strains the silicon in the upper relaxed surface layer and base layer. The gap around the suspended stack is then filled with a support dielectric, and the strained surface layer of crystalline silicon is available for MOSFET manufacture.

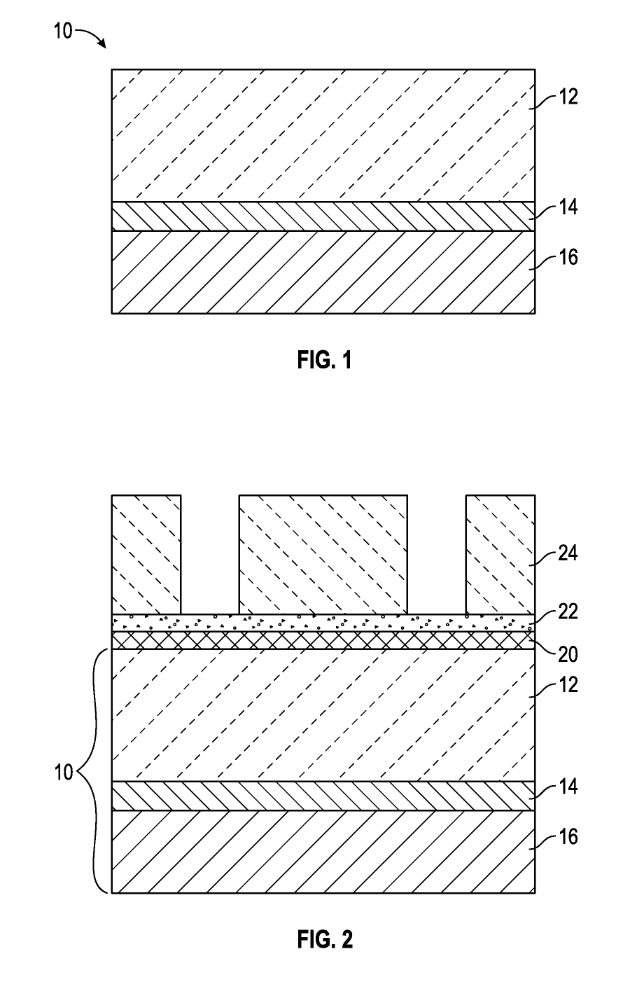

FIG. 1 illustrates a silicon on insulator (SOI) substrate 10, which includes a device layer 12 overlying a buried dielectric 14, which in turn overlies a handle layer 16, and the device layer 12. The device layer 12 is typically intended for integrated circuit manufacture. As used herein, the terms “overlying” and “over” mean “on” (such that the device layer 12 physically contacts the buried dielectric 14), or “above” (such that another material layer may lie in between the device layer 12 and the buried dielectric 14). The device layer 12 is a monocrystalline silicon material that may be lightly doped without significant changes to the silicon crystalline structure. The silicon in the device layer 12 is in a relaxed state, so the silicon atoms are at a normal crystalline silicon interatomic distance. The normal crystalline silicon interatomic distance is the interatomic distance of silicon atoms in a pure silicon crystal. The buried dielectric 14 is silicon oxide in some embodiments, but other dielectrics could also be used. The handle layer 16 is also relaxed monocrystalline silicon, which may or may not be lightly doped in different embodiments. SOI substrates 10 are commercially available, such as from Ultrasil Corporation or Semiconductor Wafer, Inc.

FIGS. 2-4 illustrate an exemplary embodiment for depositing a shallow trench isolation dielectric in the SOI substrate 10. A pad silicon oxide layer 20 is formed on an exposed surface of the device layer 12. The pad silicon oxide layer 20 is formed by placing the exposed surface of the device layer 12 in an oxidizing ambient at an elevated temperature, where the pad silicon oxide layer 20 grows from the exposed surface of the device layer 12. Oxidizing ambients include oxygen, water vapor and oxygen, and various nitrogen-oxygen compounds. Hydrochloric acid may be included in the oxidizing ambient at low concentrations. Elevated temperatures from about 700° C. to about 1,300° C. are effective. A silicon nitride layer 22 is deposited overlying the pad silicon oxide layer 20, where the silicon nitride layer 22 serves as an etch mask. The silicon nitride layer 22 is deposited by the reaction of ammonia and dichlorosilane in a low pressure chemical vapor deposition furnace. An STI photoresist layer 24 is deposited overlying the silicon nitride layer 22, and patterned to the shape of a desired trench. The STI photoresist layer 24 (and other photoresist layers described below) is deposited by spin coating, patterned by exposure to light or other electromagnetic radiation, and the desired locations are removed with an organic solvent.

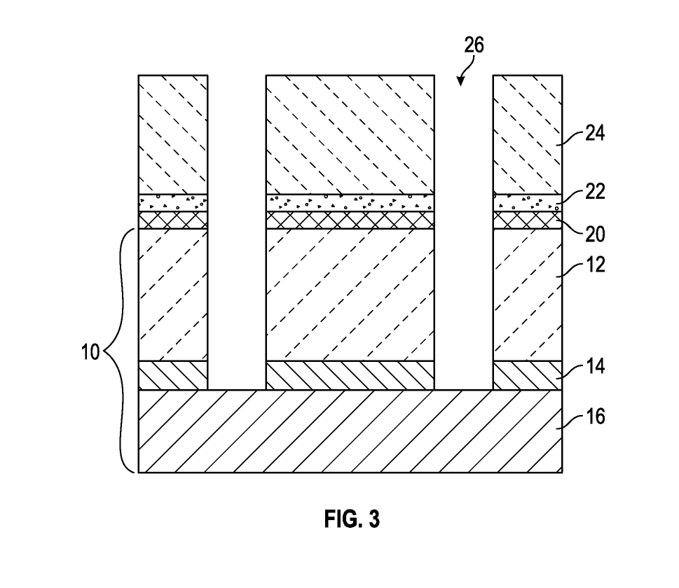

A trench 26 is then anisotropically etched through the silicon nitride layer 22, the pad silicon oxide layer 20, the device layer 12, and the buried dielectric 14, as illustrated in FIG. 3. The trench 26 is etched with a reactive ion etch (RIE), which may be in multiple steps, using a variety of gases, such as carbon tetrafluoride at a temperature of about 20 to about 60° C., followed by sulfur dioxide, followed by carbon tetrafluoride, followed by chlorine/nitrogen trifluoride/hydrogen bromide/trifluoro methane. The trench 26 extends through the buried dielectric 14 to the handle layer 16, and the trench 26 is relatively wide in an exemplary embodiment, such as about 0.5 micron to about 3 microns. The trench 26 is formed in a pattern, such as a quadrilateral pattern, so the trench 26 isolates sections of the device layer 12. After the trench 26 is etched, the STI photoresist 24 is removed, such as with an oxygen containing plasma.

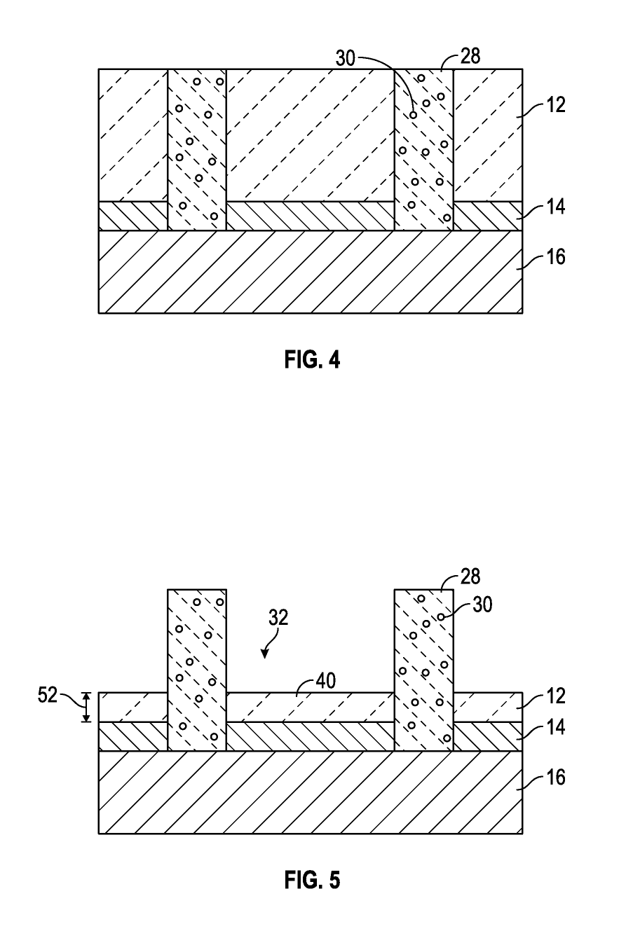

Reference is now made to FIG. 4, with continuing reference to FIG. 3. A shallow trench isolation dielectric 28 (STI dielectric) is deposited in the trench 26 and overlying the silicon nitride layer 22. The STI dielectric 28 is doped with an etch resistant dopant 30 while it is deposited in the trench. In one embodiment, the STI dielectric 28 is silicon oxide, and the etch resistant dopant 30 is carbon or fluorine, but other dielectrics and other etch resistant dopants 30 can also be used. The STI dielectric 28 and the etch resistant dopant 30 are deposited by low pressure chemical vapor deposition (LPCVD). A variety of deposition gases can be used to deposit silicon oxide, including silane and oxygen, dichlorosilane and nitrous oxide, or tetraethylorthosilicate. In an exemplary embodiment where carbon is the etch resistant dopant 30, methane and acetylene are added to the deposition gas as a carbon source for the etch resistant dopant 30. As described in more detail below, in embodiments where the STI dielectric 28 and the buried dielectric 14 both include silicon oxide, the etch resistant dopant 30 decreases the etch rate of the STI dielectric 28 for silicon oxide selective wet etchants, such as hydrofluoric acid. Any overburden of STI dielectric 28, the silicon nitride layer 22, and the pad silicon oxide layer 20 overlying the device layer 12 are removed, such as by chemical mechanical planarization.

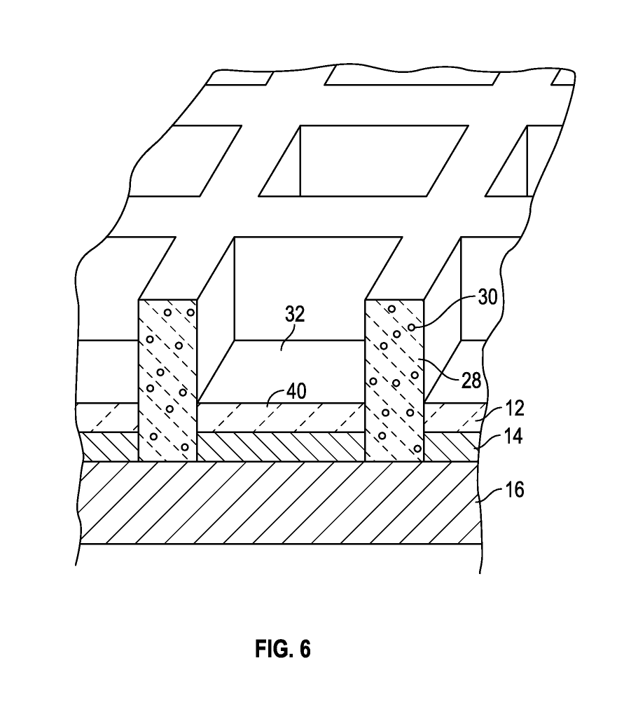

Referring now to FIGS. 5 and 6, most of the silicon from the device layer 12 is removed to form a relatively thin base layer 40 of monocrystalline silicon. In this regard, the device layer 12 is divided into a plurality of islands 32 by the STI dielectric 28. The STI dielectric 28 is formed in a pattern, such as quadrilateral pattern, to produce islands 32 of monocrystalline silicon from the device layer 12. The base layer 40 has a base layer thickness 52 of about 5 to about 10 nanometers in some embodiments, but other thicknesses are also possible. In an exemplary embodiment, a plasma etch with chlorine or a mixture of hydrogen bromide and oxygen is used to remove the silicon from the device layer 12. A photoresist layer (not shown) can be deposited and patterned to protect selected areas or islands 32 from etching, if desired. FIG. 6 provides a perspective view of an exemplary embodiment where the islands 32 are separated by the STI dielectric 28, and where the device layer 12 has been etched down to a thin base layer 40. In alternative embodiments (not shown), some of the islands 32 are not etched to a thin base layer 40 such that the silicon from the device layer 12 is about flush with the top of the STI dielectric 28. Any islands 32 that are not etched are used as a relaxed silicon substrate, such that selected areas or islands 32 of the SOI substrate 10 are relaxed while the predetermined etched islands 32 are strained, as described below.

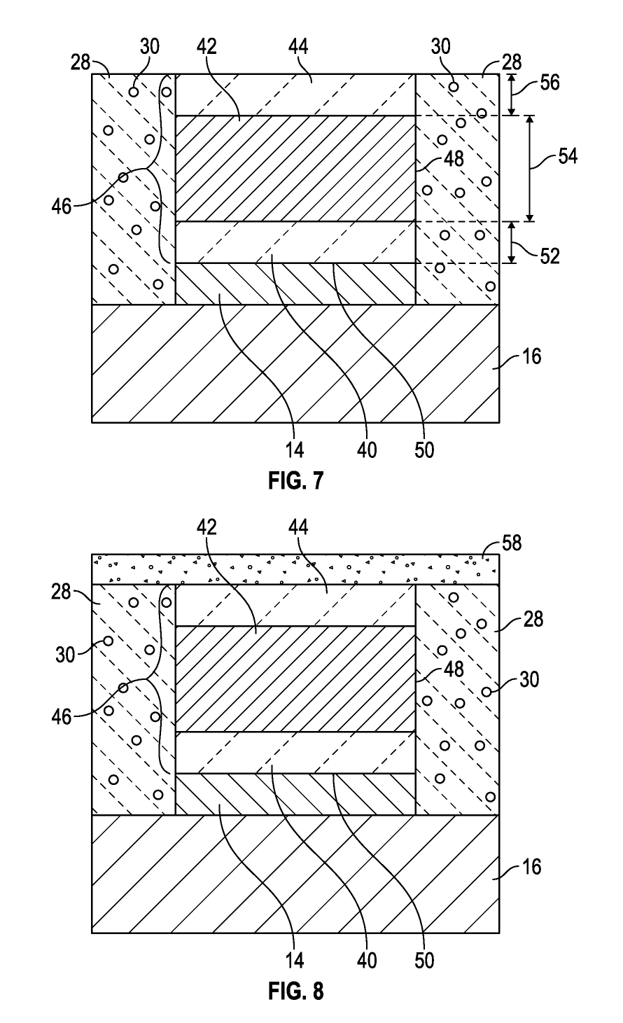

Referring now to FIG. 7, in an embodiment an intermediate layer 42 is deposited overlying the base layer 40, and then a surface layer 44 is deposited overlying the intermediate layer 42. The base layer 40, intermediate layer 42, and surface layer 44 form a stack 46, with stack sides 48 and a stack bottom 50. The stack sides 48 are adjacent to the STI dielectric 28, and the stack bottom 50 is adjacent to, and overlies, the buried dielectric 14. Therefore, the stack 46 is confined and held in place by the STI dielectric 28 and the buried dielectric 14. The intermediate layer 42 is monocrystalline silicon germanium that is epitaxially grown from the monocrystalline silicon in the base layer 40. In an exemplary embodiment, the ratio of silicon to germanium is about constant throughout the intermediate layer 42, so the intermediate layer 42 does not have a graduated germanium concentration. The surface layer 44 is monocrystalline silicon epitaxially grown from the monocrystalline silicon germanium in the intermediate layer 42. Epitaxial growth produces material that extends and adds to an existing crystalline structure, so the crystalline structure from the silicon in the base layer 40 is extended in the intermediate layer 42, and then further extended in the surface layer 44 through the crystalline structure in the intermediate layer 42. In an exemplary embodiment, the intermediate layer 42 is grown by molecular beam epitaxy, where the base layer 40 is exposed to beams of atomic germanium and silicon. The surface layer 44 is grown by passing a silicon source, such as a silane or silicon tetrachloride, over the heated intermediate layer 42. Ionized doping impurities can be added if desired.

There is a normal crystalline interatomic distance in silicon, with a normal lattice spacing of about 5.4 angstroms. Germanium can be freely substituted into the crystal structure at any concentration, but the germanium atom is larger than the silicon atom. Therefore, the normal crystalline interatomic distance in a crystal of silicon mixed with germanium is larger than the normal interatomic distance in a pure silicon crystal. When a silicon germanium crystal is grown on a pure silicon crystal, the crystal structure of the silicon germanium is strained because the interatomic distances in the pure silicon crystal are incorporated into the silicon germanium crystal. The larger germanium atoms produce larger natural interatomic distances in the crystal, but the crystal structure of the silicon base layer 40 prevents the silicon germanium crystal from forming at its larger natural interatomic distance. Therefore, the silicon germanium crystal is distorted parallel to the direction of growth, which is a compressive strain.

The crystalline silicon in the base layer 40 is relaxed, which means the silicon atoms are at the normal crystalline interatomic distance for silicon. The strained crystalline silicon germanium in the intermediate layer 42 conforms to the normal crystalline silicon interatomic distances in the base layer 40. The amount of strain is adjusted by varying the concentration of germanium in the intermediate layer 42. In an exemplary embodiment, the intermediate layer 42 is 10 atomic percent germanium, but other concentrations and associated strain levels are also possible. The base layer 40 and surface layer 44 include less germanium than the intermediate layer 42, and the base layer 40 and surface layer 44 include less than 1 atomic percent germanium in some embodiments. In an alternate embodiment, the base layer 40 and surface layer 44 include less than 0.1 atomic percent germanium.

The silicon in the surface layer 44 is relaxed, because it is grown on the strained silicon germanium of the intermediate layer 42. The crystal structure of the silicon germanium in the intermediate layer 42 conforms to the atomic spacing of the silicon base layer 40, so the crystalline interatomic spacing from the base layer 40 is carried through the intermediate layer 42 to the silicon surface layer 44. Therefore, the base layer 40 and the surface layer 44 are both relaxed, and the intermediate layer 42 is strained. The stack 46 is confined and held in place by the STI dielectric 28 and the buried dielectric 14, so the crystal structure cannot shift or change. Thus, the intermediate layer 42 is maintained in a strained crystalline structure.

The base layer 40 has a base layer thickness 52, the intermediate layer 42 has an intermediate layer thickness 54, and the surface layer 44 has a surface layer thickness 56. The intermediate layer thickness 54 is larger than either the base layer thickness 52 or the surface layer thickness 56, and in some embodiments the intermediate layer thickness 54 is more than the sum of the base layer thickness 52 and the surface layer thickness 56. In some embodiments, the intermediate layer thickness 54 is about 3 times the surface layer thickness 56, and in other embodiments the intermediate layer thickness 54 is from about 3 times to about 10 times the surface layer thickness 56. The intermediate layer thickness 54 is also from about 3 times to about 10 times the base layer thickness 52. In an exemplary embodiment, the base layer thickness, indicated by double headed arrow 52, is from about 5 nanometers (nm) to about 10 nm, the intermediate layer thickness, indicated by double headed arrow 54, is about 30 nm or less, and the surface layer thickness, indicated by double headed arrow 56, is about 10 nm. Silicon germanium layers with about 10 atomic percent germanium that are thicker than about 30 nm may begin to relax, so the intermediate layer thickness 54 and the atomic percent of germanium are adjusted to maintain the strain in the intermediate layer 42. The larger intermediate layer thickness 54 results in more atoms in the intermediate layer 42 than in the base layer 40 and the surface layer 44, and the strained atoms exert pressure to change to a relaxed state. The larger number of atoms in the intermediate layer 42 exerts more pressure to relax the crystal structure than the combined base layer 40 and surface layer 44, but the crystal structure cannot change due to the confines of the adjacent STI dielectric 28 and the buried dielectric 14.

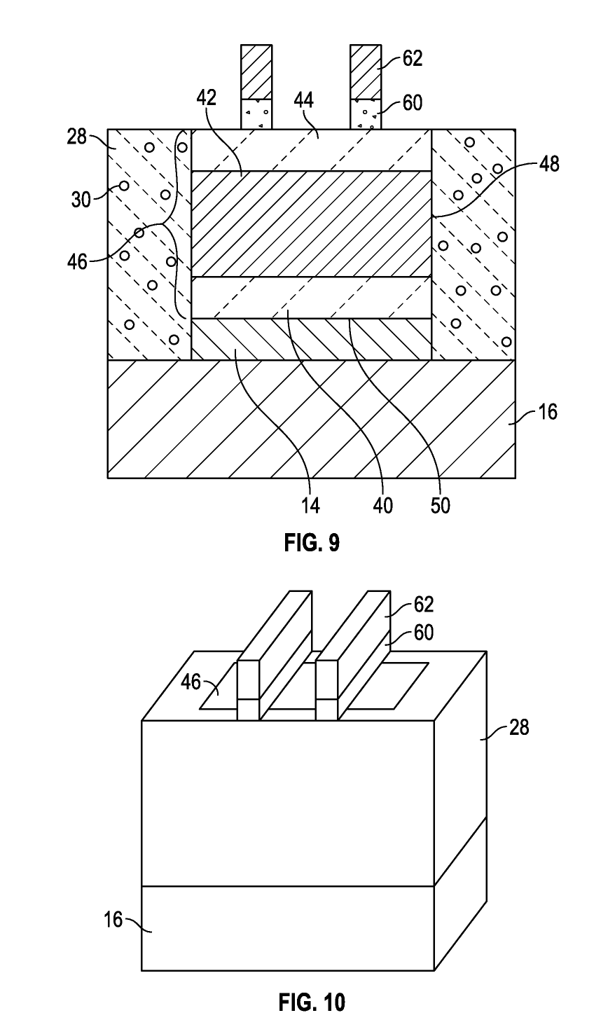

A bridge layer 58 is deposited overlying the surface layer 44 of the stack 46 and the upper surface of the STI dielectric 28, as illustrated in FIG. 8. In an exemplary embodiment, the bridge layer 58 is silicon nitride, and is deposited using chemical vapor deposition. The bridge layer 58 forms a bond to the surface layer 44 of the stack 46, and to the surface of the STI dielectric 28. Referring now to FIG. 9, with continuing reference to FIG. 8, a bridge 60 is formed from the bridge layer 58, and a plurality of bridges 60 are formed overlying the stack 46 in some embodiments. The bridge 60 is formed by removing the bridge layer 58 from all areas except for the location of the bridge 60. A bridge photoresist 62 is deposited over the bridge layer 58, patterned and removed to leave only the bridge photoresist 62 overlying where bridge 60 will be formed. The exposed portions of the bridge layer 58, which are not a part of the bridge 60, are then removed by a plasma etch. The remaining bridge 60 overlies the stack 46 and extends over a portion of the adjacent STI dielectric 28, as illustrated in FIG. 10. In some embodiments (not shown), the bridge 60 extends over a plurality of stacks 46 and STI dielectrics 28 positioned between the stacks 46. The remaining bridge photoresist 62 is then removed.

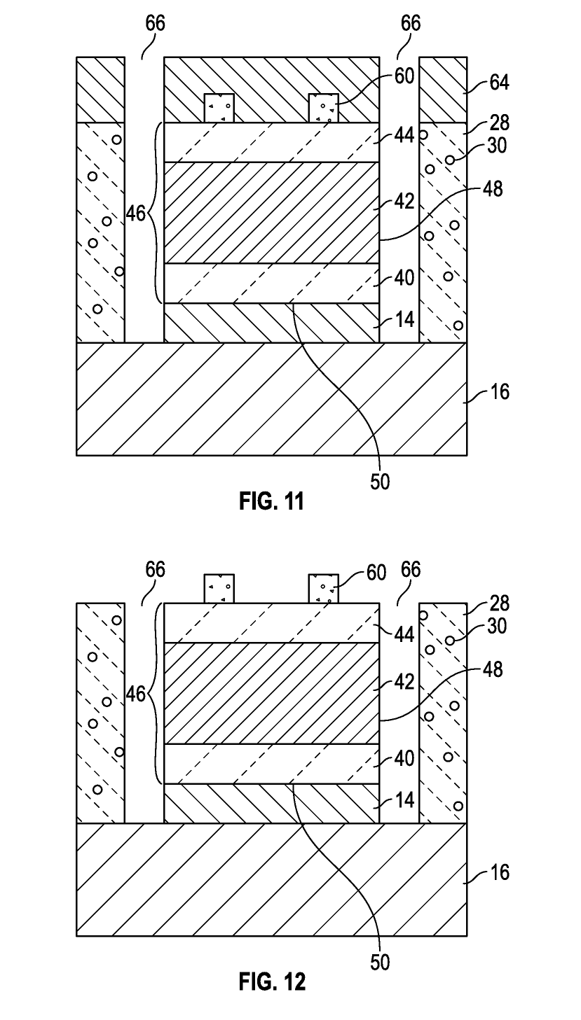

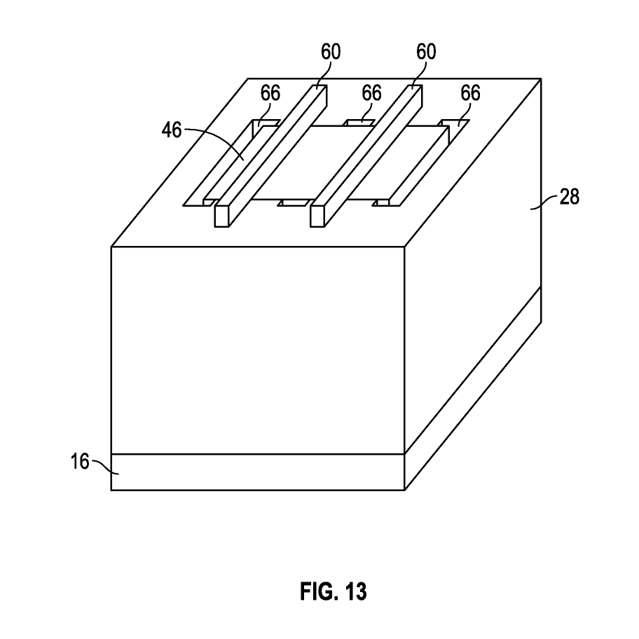

Referring now to FIG. 11, a suspension photoresist 64 is deposited overlying the stack 46, the bridge 60, and the STI dielectric 28. The suspension photoresist 64 is patterned and developed to expose the STI dielectric 28 adjacent to the stack 46, and a trough 66 is etched into the STI dielectric 28 around the stack 46. The trough 66 extends through the suspension photoresist 64 and the STI dielectric 28 to the handle layer 16, so a portion of the buried dielectric 14 is exposed near the bottom of the trough 66. The trough 66 is anisotropically etched with reactive ion etching, which may be in multiple steps, using a variety of gases, such as carbon tetrafluoride at a temperature of about 20° C. followed by chlorine. After the trough 66 is formed, the suspension photoresist 64 is removed, as illustrated in FIGS. 12 and 13. The trough 66 does not extend through the bridge 60, so the portion of the STI dielectric 28 directly under the bridge 60 is not etched, and remains in place to help support the bridge 60. A small portion of the STI dielectric 28 adjacent to the bridge 60 may also be left in place to account for any misalignment when etching the trough 66. In some embodiments, about 5 nm of STI dielectric 28 are left on each side of the bridge 60 to account for misalignment when etching the trough 66, but other distances are also possible.

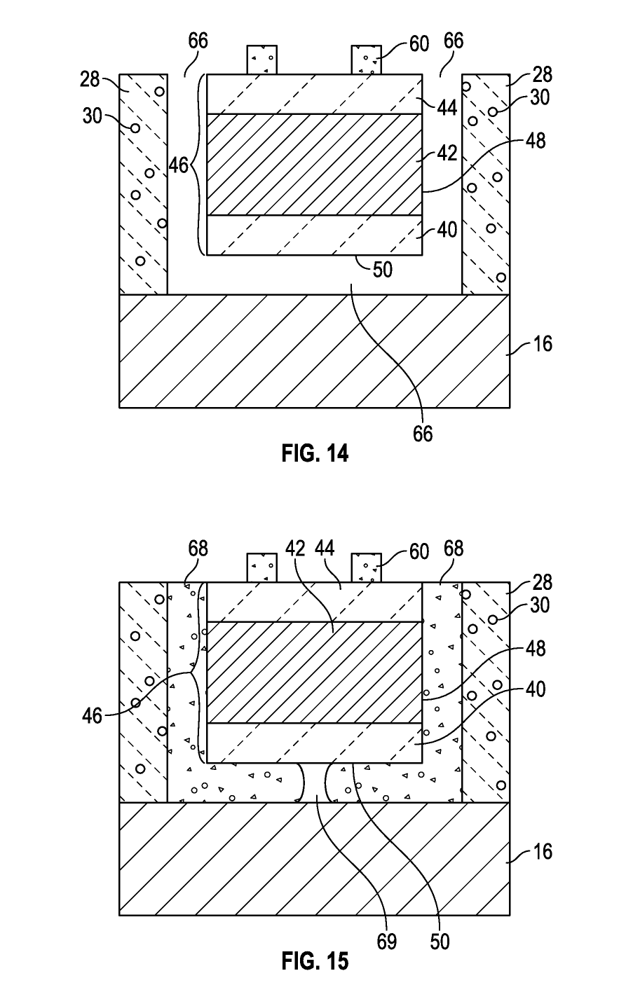

Referring now to FIG. 14, the stack 46 is suspended from the bridge 60 by removing the buried dielectric 14 from under the base layer 40. A selective wet chemistry etch is used to remove the buried dielectric 14, such as a hydrofluoric acid solution, so the buried dielectric 14 is etched much faster than the components of the stack 46. The wet chemistry etch extends the trough under the stack bottom 50. The STI dielectric 28 contains an etch resistant dopant 30 that slows the etch rate of the STI dielectric 28 from the wet chemistry etch. Therefore, the wet chemistry etch removes the buried dielectric 14 while much of the STI dielectric 28 remains in place. As mentioned earlier, a relatively thick STI dielectric 28 is formed to account for some etching, because the etch resistant dopant 30 in the STI dielectric 28 slows the etch rate, but does not completely stop the etch rate of the STI dielectric 28. The duration of the wet chemistry etch is set to remove the buried dielectric 14 from underneath the base layer 40, and still leave a portion of the STI dielectric 28 in place. The duration of the wet chemistry etch is sufficient to remove the STI dielectric 28 underneath the bridge 60 and adjacent to the stack 46 in some embodiments, but in other embodiments some STI dielectric remains adjacent to the stack 46 underneath the bridge 60.

The intermediate layer 42 relaxes when the stack 46 is suspended, and the base layer 40 and the surface layer 44 become strained. The strain in the base layer 40 and the surface layer 44 is a tensile strain that stretches the silicon atoms towards the stack sides 48. The STI dielectric 28 and the buried dielectric 14 adjacent to the stack 46 had prevented any change or shift in the crystalline structure of the stack 46, because there was no room for any movement. As previously mentioned, the intermediate layer thickness 54 is larger than the base layer thickness 52 and the surface layer thickness 56, so the intermediate layer 42 has more atomic force urging the atoms into a normal crystalline interatomic distance. The larger atomic force from the intermediate layer 42 causes the crystalline structure in the stack 46 to adjust when suspended, because the stack 46 is no longer confined by the STI dielectric 28 and buried dielectric 14. The base layer 40, intermediate layer 42, and the surface layer 44 all incorporate the same monocrystalline structure, because the intermediate layer 42 and surface layer 44 were epitaxially grown (directly or indirectly) from the base layer 40. The change in the crystalline strain between the intermediate layer 42, the base layer 40, and surface layer 44 occurs in embodiments where some STI dielectric 28 remains adjacent to the stack 46 underneath the bridge 60, because the small amount of STI dielectric 28 remaining adjacent to the stack 46 does not provide sufficient support to maintain the strained crystalline structure in the intermediate layer 42. The relaxation of the intermediate layer 42 crystal structure can be rapid or gradual.

The suspended stack 46 has limited structural stability, so a support dielectric 68 is deposited in the trough 66 after the intermediate layer 42 relaxes, as illustrated in FIG. 15. In an exemplary embodiment, the support dielectric 68 is silicon oxide deposited with a flowable oxide capable of filling restricted gaps and narrow spaces. An example of a flowable oxide that can be used here includes FOX®, available from Dow Corning. The support dielectric 68 is positioned between the stack side 48 and the STI dielectric 28, and also between the stack bottom 50 and the handle layer 16. The flowable oxides are steam annealed for densification after filling the trough 66. The trough 68 has a high aspect ratio, so there may be one or more gaps 69 in the support dielectric 68. However, even if gaps 69 are present, the support dielectric 68 provides sufficient structural stability to the stack 46 for further processing and use. Gaps 69, if present, do not interfere with the operation or utilization of the stack 46.

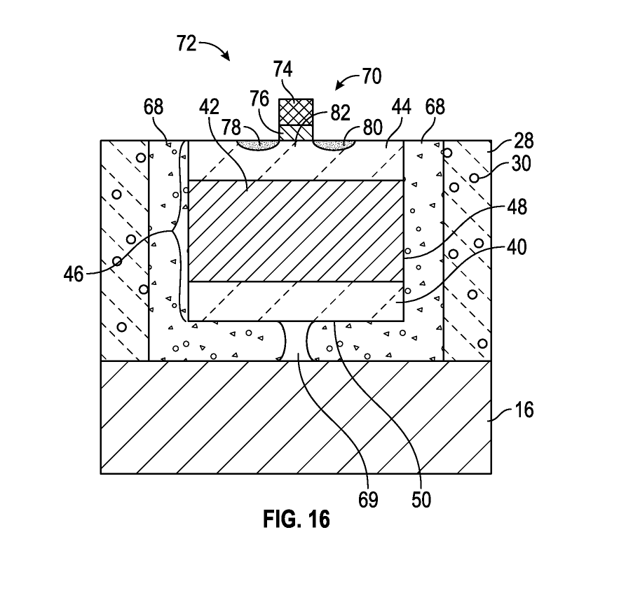

Reference is now made to FIG. 16. In an exemplary embodiment, a transistor 70 is manufactured on the surface layer 44 and incorporated into an integrated circuit 72. The transistor 70 includes a gate 74 overlying a gate insulator 76, and the gate insulator 76 overlies the surface layer 44. A source 78 and drain 80 are formed on opposite sides of the gate 74. The silicon in the surface layer 44 is strained, which increases electron mobility in a channel 82 under the gate insulator 76. In some embodiments, the transistor 70 is an N type transistor 70, but the transistor 70 is a P type in other embodiments. Fabrication of the integrated circuit 72 may thereafter continue with further processing steps that can be performed to complete fabrication of the device, as are well known in the art. The subject matter disclosed herein is not intended to exclude any subsequent processing steps to form and test the integrated circuit 72, as are known in the art. Furthermore, with respect to any of the process steps described above, one or more heat treating and/or annealing procedures can be employed after the deposition of a layer, as is known in the art.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

1. An integrated circuit comprising:
a stack comprising a surface layer, an intermediate layer, and a base layer, wherein the surface layer comprises crystalline silicon that is strained such that silicon atoms are stretched beyond a normal crystalline silicon interatomic distance, the intermediate layer comprises crystalline silicon germanium, and the base layer comprises crystalline silicon that is strained such that the silicon atoms are stretched beyond the normal crystalline silicon interatomic distance, wherein the surface layer overlies the intermediate layer, and the intermediate layer overlies the base layer, wherein the stack comprises a plurality of stack sides and a stack bottom;
a support dielectric adjacent to the stack sides and the stack bottom, wherein the support dielectric comprises a gap.

2. The integrated circuit of claim 1 wherein the gap underlies the stack bottom.

3. The integrated circuit of claim 1 further comprising a shallow trench isolation dielectric, wherein the support dielectric is positioned between the shallow trench isolation dielectric and the stack sides.

4. The integrated circuit of claim 3 wherein the shallow trench isolation dielectric comprises silicon oxide.

5. The integrated circuit of claim 3 wherein the shallow trench isolation dielectric comprises an etch resistant dopant.

6. The integrated circuit of claim 5 wherein the etch resistant dopant comprises carbon.

7. The integrated circuit of claim 1 wherein the support dielectric comprises silicon oxide.

8. The integrated circuit of claim 1 further comprising a handle layer, wherein the support dielectric is positioned between the handle layer and the stack bottom.

9. The integrated circuit of claim 1 wherein the intermediate layer has an intermediate layer thickness, the surface layer has a surface layer thickness, and the intermediate layer thickness is about 3 times the surface layer thickness.

10. The integrated circuit of claim 1 wherein a ratio of germanium to silicon is about constant in the intermediate layer.

11. The integrated circuit of claim 1 further comprising a transistor gate overlying the surface layer.

12. An integrated circuit comprising:
a handle layer comprising crystalline silicon;
a support dielectric overlying the handle layer, wherein the support dielectric comprises a gap; and
a stack overlying the support dielectric and the gap, the stack comprising a surface layer, an intermediate layer, and a base layer, wherein the surface layer comprises crystalline silicon, the intermediate layer comprises crystalline silicon germanium, the base layer comprises crystalline silicon, and wherein the surface layer is overlying the intermediate layer, the intermediate layer is overlying the base layer, and the base layer is overlying the support dielectric.

13. The integrated circuit of claim 12 further comprising a transistor gate overlying the surface layer.

14. The integrated circuit of claim 12 wherein the intermediate layer has an intermediate layer thickness, the surface layer has a surface layer thickness, and the intermediate layer thickness is about 3 times the surface layer thickness.

15. The integrated circuit of claim 12 wherein silicon atoms in the surface layer are stretched beyond a normal crystalline silicon interatomic distance.

16. The integrated circuit of claim 12 wherein the stack comprises stack sides, and wherein the support dielectric is adjacent to the stack sides.

17. The integrated circuit of claim 16 further comprising a shallow trench isolation dielectric, wherein the support dielectric is positioned between the stack sides and the shallow trench isolation dielectric.

18. The integrated circuit of claim 17 wherein the shallow trench isolation dielectric comprises an etch resistant dopant.

19. The integrated circuit of claim 18 wherein the etch resistant dopant comprises carbon.

20. A method of producing an integrated circuit comprising:
etching a trench in a silicon on insulator substrate, wherein the silicon on insulator substrate comprises a buried dielectric;
forming a shallow trench isolation dielectric in the trench;
creating a stack comprising an intermediate layer overlying a base layer and a surface layer overlying the intermediate layer, wherein the surface layer comprises crystalline silicon, the intermediate layer comprises crystalline silicon germanium, and the base layer comprises crystalline silicon, wherein the stack comprises stack sides and a stack bottom, and wherein the stack sides are adjacent the shallow trench isolation dielectric and the stack bottom is overlying the buried dielectric;
forming a bridge overlying the stack and a portion of the shallow trench isolation dielectric;
suspending the stack from the bridge by removing the shallow trench isolation dielectric from adjacent the stack sides and removing the buried dielectric from underneath the stack bottom; and
supporting the stack by depositing a support dielectric underneath the stack bottom and adjacent to the stack sides.
